(19) United States
(12) Patent Application Publication
(10) Pub. No.: US 2009/0309617 A1
(43) Pub. Date: Dec. 17, 2009

(54) Biosensor antibody functional mapping

(76) Inventors: Ye Fang, Painted Post, NY (US); Jun Xi, Painted Post, NY (US)

Correspondence Address: CORNING INCORPORATED, SP-TI-3-1, CORNING, NY, 14831, US

(21) Appl. No.: 11/895,542

(22) Filed: Aug. 24, 2007

(51) Int. Cl. G01R 27/08

(52) U.S. Cl. 324/692

(57) ABSTRACT

Disclosed is a system and method for measuring aspects of antibody function in live-cell systems as defined herein. The system and method also provide a method to measure prophylaxis or remedial aspects of antibody therapeutic candidates in a live-cell or a live-cell model.

The entire disclosure of any publications, patents, and patent documents mentioned herein are incorporated by reference.

### BACKGROUND

The disclosure relates to functional mapping of an antibody with a biosensor, and more specifically to methods for biosensor live-cell sensing of antibody function and cellular response.

### SUMMARY

The disclosure provides a method to examine the function of one or more antibodies against a specific cellular target using a biosensor, such as an optical biosensor, in a cellular environment. The disclosure provides methods that are suitable for a cell surface antibody target, an intracellular antibody target, or both. The disclosure provides antibody functional mapping methods that can be achieved, for example, in ligand-dependent mode, ligand-independent mode, or both modes.

### BRIEF DESCRIPTION OF THE DRAWINGS

FIGS. 1A to 1F illustrate real-time kinetic responses of quiescent A431 cells induced by 32 nM epidermal growth factor (EGF) against various anti-epidermal growth factor receptors (anti-EGFRs), in embodiments of the disclosure.

FIG. 2A illustrates the dose-dependent real-time kinetic responses of quiescent A431 cells induced by 32 nM of EGF against varying concentrations of anti-EGFR (528), in embodiments of the disclosure.

FIG. 2B shows normalized amplitudes of negative dynamic mass redistributions (N-DMRs) plotted as a function of the concentration of anti-EGFR (528), in embodiments of the disclosure.

FIGS. 3A and 3B show dose-dependent real-time kinetic responses of quiescent A431 cells induced by 5 mM of methyl-β-cyclodextrin against varying concentrations of monoclonal anti-EGFR (clone C11), in embodiments of the disclosure.

FIGS. 4A and 4B show dose-dependent real-time kinetic responses of quiescent A431 cells induced by 5 mM of methyl-β-cyclodextrin against varying concentrations of monoclonal anti-Her2 (clone 9G6), in embodiments of the disclosure.

FIG. 5 is a schematic representation of the epidermal growth factor receptor (EGFR) having exemplary structural domains, and showing potential extracellular (cell surface) and intracellular points of antibody interaction, in embodiments of the disclosure.

FIG. 6 is a schematic representation of possible exemplary antibody interactions and outcomes with a cellular target such as the extracellular region of the epidermal growth factor receptor (EGFR), in embodiments of the disclosure.

FIG. 7 illustrates real time kinetics of quiescent A431 cells in response to stimulation with 64 nM EGF, in embodiments of the disclosure.

FIGS. 8A and 8B illustrate real time kinetics of quiescent A431 cells pre-treated with varying concentrations of anti-EGFR (R1 clone), for about 2 hrs and 24 hrs, respectively, before being induced by 64 nM EGF, in embodiments of the disclosure.

FIGS. 9A to 9C show the impact of the short (2 hr) pre-treatment of A431 cells with anti-EGFR (R1 clone) at different doses on the amplitudes of various DMR events induced by 64 nM EGF, in embodiments of the disclosure.

FIGS. 10A to 10C show the impact of extended (24 hr) pre-treatment of A431 cells with anti-EGFR (R1 clone) at different doses on the amplitudes of various DMR events induced by 64 nM EGF, in embodiments of the disclosure.

### DETAILED DESCRIPTION

Various embodiments of the disclosure will be described in detail with reference to drawings, if any. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

### DEFINITIONS

“Assay,” “assaying” or like terms refers to an analysis to determine, for example, the presence, absence, quantity, extent, kinetics, dynamics, or type of a cell's optical or bioimpedance response upon contact or stimulation with a stimulus, for example, an exogenous or endogenous stimuli, such as an antibody, an antibody mimic, a ligand candidate compound, a viral particle, a pathogen, or like entity.

“Attach,” “attachment,” “adhere,” “adhered,” “adherent,” “immobilized,” or like terms generally refer to immobilizing or fixing, for example, a surface modifier substance, a compatibilizer, a cell, a ligand candidate compound, or like entities of the disclosure, to a surface, such as by physical absorption, chemical bonding, and like processes, or combinations thereof. Particularly, “cell attachment,” “cell adhesion,” or like terms refer to the interacting or binding of cells to a surface, such as by culturing, or interacting with cell anchoring materials (e.g., extracellular matrices, adhesion complexes, etc.), a compatibilizer (e.g., fibronectin, collagen, lamin, gelatin, polylysine, etc.), or both.

“Adherent cells” refers to a cell or a cell line or a cell system, such as a prokaryotic or eukaryotic cell, that remains associated with, immobilized on, or in certain contact with the outer surface of a substrate. Such type of cells after culturing can withstand or survive washing and medium exchanging process, a process that is prerequisite to many cell-based assays. “Weakly adherent cells” refers to a cell or a cell line or a cell system, such as a prokaryotic or eukaryotic cell, which weakly interacts, or associates or contacts with the surface of a substrate during cell culture. However, these types of cells, for example, human embryonic kidney (HEK) cells, tend to dissociate easily from the surface of a substrate by physically disturbing approaches such as washing or medium exchange. “Suspension cells” refers to a cell or a cell line that is preferably cultured in a medium wherein the cells do not attach or adhere to the surface of a substrate during the culture. “Cell culture” or “cell culturing” refers to the process by which either prokaryotic or eukaryotic cells are grown under controlled conditions. “Cell culture” not only refers to the culturing of cells derived from multicellular eukaryotes, especially animal cells, but also the culturing of complex tissues and organs.

“Cell” or like term refers to a small usually microscopic mass of protoplasm bounded externally by a semipermeable membrane, optionally including one or more nuclei and various other organelles, capable alone or interacting with other like masses of performing all the fundamental functions of life, and forming the smallest structural unit of living matter capable of functioning independently including synthetic cell constructs, cell model systems, and like artificial cellular systems.

“Cell system” or like term refers to a collection of more than one type of cells (or differentiated forms of a single type of cell), which interact with each other, thus performing a biological or physiological or pathophysiological function. Such cell system includes an organ, a tissue, a stem cell, a differentiated hepatocyte cell, or like systems.

“Antibody,” “Ab” or like terms refer generally to a protein biomolecule, or a biomolecule mimic, typically having a Y-shaped and found in blood or other bodily fluids of vertebrates, including soluble, membrane bound, membrane-liberated, or like forms, and monoclonal, polyclonal, natural, synthetic, engineered, and like forms. Antibodies are used by the immune system to identify and neutralize foreign objects or pathogens, such as bacteria and viruses, by reaction with surface antigens. As used herein an antibody, such as an EGFR antibody, can be designated as, for example, anti-EGFR (clone XX), anti-EGFR (cl. XX), anti-EGFR (XX), or like designations.

“Marker” or like term refers to a molecule, a biomolecule, or a biological material that is able to modulate the activities of at least one cellular target (e.g., a G_{q}-coupled receptor, a Gₛ-coupled receptor, a Gᵢ-coupled receptor, a G_{12/13}-coupled receptor, an ion channel, a receptor tyrosine kinase, a transporter, a sodium-proton exchanger, a nuclear receptor, a cellular kinase, a cellular protein, etc.), and can result in a reliably detectable output or signal measurable by a biosensor. Depending on the class of the intended cellular target and its subsequent cellular event(s), a marker can be, for example, an activator, such as an agonist, a partial agonist, an inverse agonist, for example, for a G protein-coupled receptor (GPCR), a receptor tyrosine kinase (RTK), an ion channel, a nuclear receptor, a cellular enzyme adenylate cyclase, and like markers. The marker can be, for example, a ligand that binds to and activates a specific target, or a molecule that binds to and activates another distinct target, which in turn transactivates the specific target.

“Detect,” “detection,” “detecting,” or like terms refer to an ability of the apparatus and methods of the disclosure to discover or sense the interaction of an antibody on cell-signaling of the cellular target induced by a marker with a biosensor.

“Therapeutic candidate compound,” “therapeutic candidate,” “prophylactic candidate,” “prophylactic agent,” “ligand candidate,” or like terms refer to a molecule or material, naturally occurring or synthetic, that is of interest for its potential to interact with a cell attached to the biosensor. A therapeutic or prophylactic candidate can include, for example, a chemical compound, a biological molecule, a peptide, a protein, a biological sample, a drug candidate small molecule, a drug candidate biologic molecule, a drug candidate small molecule-biologic conjugate, and like materials or molecular entity, or combinations thereof, which can specifically bind to or interact with at least one of a cellular target or a pathogen target such as a protein, DNA, RNA, an ion, a lipid or like structure or component of a living cell.

“Biosensor” or like terms refer to a device for the detection of an analyte that combines a biological component with a physicochemical detector component. The biosensor typically comprised of three parts: a biological component or element (such as tissue, microorganism, pathogen, cells, or combinations thereof), a detector element (which operates, e.g., in a physicochemical manner such as optical, piezoelectric, electrochemical, thermometric, or magnetic), and a transducer associated with both components. The biological component or element can include, for example, a living cell, a pathogen, or combinations thereof. In embodiments, an optical biosensor can comprise an optical transducer for converting a molecular recognition or molecular stimulation event in, for example, a living cell, a pathogen, or combinations thereof, into a quantifiable signal.

“Epidermal growth factor” or “EGF” refers to a growth factor that plays a significant role in the regulation of cell growth, proliferation, and differentiation. Human EGF is a 6,045 Da protein having 53 amino acid residues and three intramolecular disulfide bonds. EGF acts by binding with high affinity to EGFR on the cell surface and stimulating the intrinsic protein-tyrosine kinase activity of the receptor. The tyrosine kinase activity in turn initiates a signal transduction cascade which results in a variety of biochemical changes within the cell, such as a rise in intracellular calcium levels, increased glycolysis and protein synthesis, and increases in the expression of certain genes, including the gene for EGFR that ultimately leading to DNA synthesis and cell proliferation.

“Epidermal growth factor receptor” or “EGFR” refers to a particular receptor on the cell's surface that can be activated by binding of its specific ligands, including EGF and transforming growth factor α (TGFα). The EGF receptor is a member of the ErbB family of receptors, a subfamily of four closely related receptor tyrosine kinases: EGFR (ErbB-1), HER2/c-neu (ErbB-2), Her 3 (ErbB-3) and Her 4 (ErbB-4). The related ErbB-3 and ErbB-4 receptors are activated by neuregulins (NRGs). ErbB-2 has no known direct activating ligand, and may be in an activated state constitutively. Upon activation by its growth factor ligands, EGFR undergoes a transition from an inactive monomeric form to an active homodimer, although there is evidence that preformed inactive dimers may also exist before ligand binding. In addition to forming homodimers after ligand binding, EGFR may pair with another member of the ErbB receptor family, such as ErbB2/Her2/neu, to create an activated heterodimer. There is also evidence to suggest that clusters of activated EGFRs form, although it remains unclear whether this clustering is important for activation itself or occurs subsequent to activation of individual dimers.

“Transactivation” or like terms refer to the activation of a receptor (e.g., EGFR) triggered by a ligand that binds to and activates another distinct cell receptor (e.g., a GPCR). As a result of cellular regulatory machineries, the former receptor becomes transactivated. Such transactivation is a common principle in communication between different cellular signaling systems that enables cells to integrate a multitude of signals from its environment. For example, transactivation of the EGFR represents the paradigm for cross-talk between GPCRs and RTKs (see for example, Gschwind, A., et al., “Cell Communication Networks: Epidermal Growth Factor Receptor Transactivation as the Paradigm for Interrceptor Signal Transmission,” Oncogene, (2001), 20 (13), 1594-1600). Another example is the transactivation of Kv 1.2 potassium ion channel in HEK 293 cells with carbachol, a GPCR muscrunic receptor ligand. A transactivating ligand, transactivating marker, or transactivating molecule refers to a ligand, marker, or molecule that can activate a target receptor of interest indirectly, possibly through intracellular regulatory or signaling mechanism(s), rather than directly binding to and activating the target receptor.

Abbreviations, which are well known to one of ordinary skill in the art, may be used (e.g., “h” or “hr” for hour or hours, “g” or “gm” for gram(s), “mL” for milliliters, and “rt” for room temperature, “nm” for nanometers, and like abbreviations).

“Include,” “includes,” or like terms means including but not limited to.

“About” modifying, for example, the quantity of an ingredient in a composition, concentrations, volumes, process temperature, process time, yields, flow rates, pressures, and like values, and ranges thereof, employed in describing the embodiments of the disclosure, refers to variation in the numerical quantity that can occur, for example, through typical measuring and handling procedures used for making compounds, compositions, concentrates or use formulations; through inadvertent error in these procedures; through differences in the manufacture, source, or purity of starting materials or ingredients used to carry out the methods; and like considerations. The term “about” also encompasses amounts that differ due to aging of a composition or formulation with a particular initial concentration or mixture, and amounts that differ due to mixing or processing a composition or formulation with a particular initial concentration or mixture. Whether modified by the term “about” the claims appended hereto include equivalents to these quantities.

“Consisting essentially of” in embodiments refers, for example, a method for characterizing antibody function, such as examining or determining antibody interaction with a cellular target with or without the presence of a marker, such as two or more markers, including a composition comprising a cell construct on the surface of the biosensor including an antibody and optionally one or more markers, and articles, devices, or apparatus of the disclosure, and can include the components or steps listed in the claim, plus other components or steps that do not materially affect the basic and novel properties of the compositions, articles, apparatus, and methods of making and use of the disclosure, such as particular reactants, particular additives or ingredients, a particular agents, a particular cell or cell line, a particular surface modifier or condition, a particular ligand candidate, or like structure, material, or process variable selected.

The indefinite article “a” or “an” and its corresponding definite article “the” as used herein means at least one, or one or more, unless specified otherwise.

Specific and preferred values disclosed for components, ingredients, additives, cell types, antibodies, and like aspects, and ranges thereof, are for illustration only; they do not exclude other defined values or other values within defined ranges. The compositions, apparatus, and methods of the disclosure include those having any value or any combination of the values, specific values, more specific values, and preferred values described herein.

In embodiments the disclosure provides biosensors, such as resonant waveguide grating (RWG) biosensors or surface plasmon resonance (SPR) biosensors, and to methods for live-cell antibody interaction and diagnosis in cellular systems, for example, immune system disorders, infection, treatment, prevention, or like applications. The disclosure also provides biosensor-based methods that can be used to identify antibody management strategies and therapies, such as an antibody for stimulation or inhibition, a neutralizing antibody for neutralizing the autocrine signaling of a cell receptor, or antibody therapeutic agents, such as remedial or prophylactic compounds or agents that can modulate antibody activity, anti-inflammatory agents, and auto-immune agents. Autocrine signaling is a form of signaling in which a cell secretes a chemical messenger (called the autocrine agent) that signals the same cell.

In embodiments, the disclosure provides a method to determine antibody function with respect to a specific cellular target using a biosensor, such as optical biosensors, in a live-cell environment.

In embodiments, the disclosure provides a method to control antibody function with respect to a specific cellular target in a live-cell environment.

In embodiments, the disclosure provides a method to modulate antibody function of one or more antibodies, such as a family of antibodies, with respect to a specific cellular target in a cellular environment in a live-cell environment.

In embodiments, the disclosure provides a method to map the function(s) of a family of antibodies against a specific cellular target using a biosensor, such as optical biosensors, in a cellular environment.

In embodiments, the disclosure provides a method to map antibody function, which method can be achieved, for example, in ligand-dependent mode, ligand-independent mode, or both modes.

In embodiments, the disclosed methods are suitable for either or both cell surface antibody targets and intracellular antibody targets.

In embodiments, the disclosure provides a method for characterizing antibody function in a live-cell, the method comprising:

providing a biosensor having a live-cell immobilized on the biosensor's surface;

contacting the immobilized cell with an antibody against a selected cellular target for a period of time;

contacting the antibody-contacted immobilized cell having the selected cellular target, with a pair of markers, the contacting can be accomplished simultaneously or sequentially;

detecting with the biosensor the effect of the antibody contact on cell-signaling of the cellular target induced by either of the first marker or the second marker; and

comparing the biosensor's output signals of the cell-signaling of the cellular target in the presence and absence of the antibody.

In embodiments, the antibody can be, for example, an auto-antibody. The body's immune system normally makes antibodies to protect the body against viruses, bacteria, and other foreign materials. These foreign materials are called antigens. In an autoimmune disorder such as lupus, the immune system cannot distinguish between foreign substances and its own cells and tissues. The immune system then makes antibodies directed against itself. These antibodies, called “auto-antibodies” (auto means ‘self’), react with the “self” antigens to form immune complexes. The immune complexes build up in the tissues and can cause, for example, inflammation, injury to tissue, and pain.

The period of time can be, for example, from about seconds to about minutes, from about minutes to about hours, from about days to about weeks, or combinations thereof, depending upon, for example, the interaction kinetics of the cell-signaling, the cellular target, the antibody, the cell type and status, and like considerations.

In embodiments, the pair of markers can comprise, for example, at least one ligand that directly activates the cellular target. In embodiments, the pair of markers can comprise, for example, at least one ligand that indirectly acts on the cellular target by way of activation, transactivation, or both. In embodiments, the pair of markers can comprise, for example, a first marker which directly binds to and activates the cellular target, and a second marker, which second marker indirectly transactivates the cellular target through a cellular regulatory path or cellular signaling path. The marker can comprise, for example, one marker, two markers, or three or more different markers. The marker can comprise, for example, at least one of: an epidermal growth factor (EGF), a methyl-β-cyclodextrin, a G protein-coupled receptor ligand that transactivates epidermal growth factor receptor, or a combination thereof.

In embodiments, contacting the immobilized cell with an antibody can comprise, for example, contacting the cell's surface with the antibody, contacting the cell intracellularly with the antibody, or combinations thereof.

In embodiments, the cellular target can comprise, for example, a feature on the cell's surface comprising, for example, at least one of a G protein-coupled receptor (GPCR), an ion channel, a receptor tyrosine kinase, an epidermal growth factor receptor (EFGR), a cytokine receptor, an immuno-receptor, an integrin receptor, an ion transporter, and like features, or combinations thereof. The cellular target can comprise, for example, an intracellular target comprising at least one of an enzyme, a kinase, a phosphatase, or combinations thereof. The cellular target can comprise, for example, a monomeric receptor, a dimeric receptor, an oligomeric receptor, or combinations thereof. The cellular target can comprise, for example, an homologous receptor complex or an heterologous oligomeric receptor complex.

In embodiments, the biosensor can comprise, for example, an impedance sensor, an evanescent wave sensor, or combinations thereof.

In embodiments, the disclosure provides a method comprising:

providing a biosensor having a live-cell immobilized on the biosensor's surface, the live-cell having at least one cellular target of interest;

incubating the immobilized cell with a protein transfection complex containing an antibody such that the antibody is taken into the cell and thereafter interacts with the cellular target of interest;

stimulating the immobilized cell with a stimulus; and

monitoring the biosensor's signature of the cell's response to the stimulus. The protein transfection complex can comprise, for example, an antibody comprising, for example, a liposome, a protein transduction agent, or a combination thereof.

In embodiments, the disclosure provides a method for characterizing antibody function against epidermal growth factor receptor (EFGR) cellular target in a live-cell, the method comprising:

providing a biosensor having a live-cell immobilized on the biosensor's surface, the immobilized cell having at least one EFGR target;

contacting the immobilized cell with an antibody against an epidermal growth factor receptor for a period of time;

contacting the antibody-contacted immobilized cell with a marker;

detecting with the biosensor the effect of the antibody contact on the cell-signaling of the EFGR cellular target induced by the marker; and

comparing the biosensor's measure of cell-signaling of the EFGR cellular target in the presence and the absence of the antibody.

### Ligand-Dependent Mode

In embodiments, the disclosure provides for the functional mapping of an antibody against a receptor using a ligand-dependent mode. A receptor is a protein found, for example, on the cell membrane or intracellularly, i.e., within the cytoplasm or cell nucleus, that binds to a specific molecule (a ligand), such as a neurotransmitter, hormone, or other substance, and initiates a cellular response to the ligand. Ligand-induced changes in the behavior of receptor proteins result in physiological changes that constitute the biological actions of the ligands. When the stimulation of the cells having the receptor with a ligand leads to a measurable biosensor output signal, the functional activity of an antibody against the receptor can be assessed by its ability to modulate the ligand-induced biosensor output signals. In embodiments, the ligand can preferably be, for example, a full agonist, a partial agonist, or an inverse agonist. Full agonists are able to activate the receptor and result in a maximum biological response. Most natural ligands are full agonists. Partial agonists are not able to activate the receptor maximally, resulting in a partial biological response compared to a full agonist. Inverse agonists are able to reduce the receptor activation by decreasing its basal activity. An antagonist can optionally be used to modulate agonist or inverse agonist activity or effects.

In embodiments, to modulate the ligand-induced cellular responses, the antibody can be mixed with the ligand at different molecular ratios (i.e., concentrations), and the mixtures can be used to stimulate the cells. The difference between the biosensor output signals (i.e., measures) induced by the ligand in the absence and presence of the antibody is an indicator of the functionality of the antibody against the receptor.

In embodiments, the antibody can be used to pre-treat the cells. The antibody-treated cells can then be stimulated with the ligand. The difference between the biosensor output signals induced by the ligand in the cells without and with a pre-treatment can be an indicator of the functionality of the antibody against the receptor. Depending on the nature of the receptor in the cells, which may be autocrine or not, the pre-treatment of the cells with the antibody can be short (e.g., 1 min, 5 min, 15 min, 30 min, 45 min, 1 hr, 2 hrs, or 5 hrs), or long (i.e., extended, e.g., 16 hrs, 1 day, 2 days or 5 days). When the receptor is autocrine, the pre-treatment of cells with the antibody is preferably long or extended.

In embodiments, the disclosure provides methods to monitor cell-antibody interaction effects, such as neutralization, in live-cell lines using, for example, Mass Redistribution Cell Assay Technology (MRCAT) with a Corning® Epic® biosensor system in a ligand-dependent mode.

### Ligand-Independent Mode

In embodiments, the disclosure provides for functional mapping of an antibody against a receptor using a ligand-independent mode. Instead of being directly activated by its own ligand(s), the receptor can be transactivated by another ligand, marker, or molecule that does not bind to the receptor directly, but can transactivate the receptor, for example, through intracellular regulatory or signaling mechanism(s). There are many examples of transactivation. For example, EGFR can be transactivated by various GPCR ligands, such as endothelin-1, thrombin, bradykinin, bombesin, carbachol, angiotensin II, substance P or LPA (oleoyl-L-α-lysophosphatidic acid) in various types of cells. Another example is EGFR, being transactivated by a cholesterol-depleting agent, methyl-β-cyclodextrin (see Y. Fang, Y., et al., “Cellular functions of cholesterol probed with optical biosensors.” Biochim. Biophys. Acta, 2006, 1763(2), 254-261, and “Non-invasive optical biosensor for assaying endogenous G protein-coupled receptors in adherent cells,” J Pharmacol. Toxicol. Methods, 2007, 55, 314-322). Another class of transactivators is, for example, a GPCR that can be activated by a ligand that binds to another GPCR in the same cell, possibly through the dimerization of both receptors.

The functionality of an antibody against a target receptor can be examined by comparing the biosensor output signals induced by a transactivating ligand in cells without or with the antibody.

The disclosure relates to biosensors, specifically optical biosensors including resonant waveguide grating (RWG) biosensors and surface plasmon resonance (SPR) for live-cell sensing methods. In embodiments, the disclosure provides methods to determine the functionality of antibodies against a specific target(s) in, for example, live-cells using label-free and manipulation-free biosensors. The method can measure an antibody binding event, such as antibody binding to its cellular target, based upon the accompanying dynamic mass redistribution (DMR) signals. These DMR signals can be further mediated through the activation of the target. The target can be activated in a ligand-dependent manner by its corresponding ligand, or transactivated in a ligand-independent manner. The disclosed methods are applicable to functional determination of an antibody based upon the antibody's impact on a cell surface target, for example, G protein-coupled receptors (GPCR), ion channels, receptor tyrosine kinases, cytokine receptors, immuno-receptors, integrin receptors, ion transporters, and like targets, since these receptors are typically located on cell surface and are directly available to antibody interaction. The disclosure also provides methods for functional determination of antibodies against intracellular targets. The antibody can be delivered intracellularly using physical or transfection approaches. For example, the antibody can be reformulated with a liposome or a protein transduction/transfection agent so that the cell can take up the antibody. Following uptake, the antibody can bind-to and interact-with its intracellular target. For examples of intracellular methods see U.S. Pat. No. 7,105,347.

Bioactive macromolecules, such as antibodies, binding proteins, transport proteins, enzymes, DNAs, RNAs, and like entities play essential roles in cellular life cycles. Use of bioactive macromolecules in therapeutic treatment methods is a major paradigm shift emerging in the pharmaceutical industry. Therapeutic biologics or protein pharmaceuticals, including secreted proteins that activate cellular receptors, for example, cytokines, growth factors and hormones, and monoclonal antibodies that prevent activation of cell-surface receptors by native ligands continues steady market growth. Monoclonal antibodies, in particular, represent the fastest growing pharma market segment. An important aspect of continued success of protein therapeutic discovery is the development of a medically relevant assay having a high throughput format that meets the increased demands of industrial research and production.

Antibodies represent a class of flexible protein molecules produced by the immune system in response to foreign molecules, such as those on the surface of an invading microorganism. Millions of different antibody molecules are present in the immune system of human beings. Each individual antibody, however, exhibits a degree of specificity toward a particular epitope of the target molecule. An immune system disorder caused by formation of antibodies against endogenous molecules and not against foreign molecules is referred as autoimmune disease. Such an antibody is called as autoantibody. Many cardiovascular complications such as hypertension, heart attack, arrhythmia, dilated cardiomyopathy, and like conditions have been related to the presence of autoantibodies, whose impact on cardiac membrane receptors could be the leading cause of those autoimmune heart diseases. Currently, there is no automated assay available for detecting the presence of these autoantibodies with high sensitivity and specificity, particularly in live-cell environments.

For a given cellular protein target, several antibodies can be artificially produced, each of which recognizes a specific epitope. An epitope is the part of a macromolecule that is recognized by the immune system, specifically by antibodies, B-cells, or cytotoxic T-cells. However, the functionality of the antibodies generated, that is the impact of antibodies on the biological functions of their intended target, is largely unknown or poorly understood.

Detecting biologically active macromolecules in a cellular environment typically calls for high specificity and sensitivity, which aspects can usually be achieved by tagging the binding partner of the molecule of interest with, for example, a radioisotope or a fluorescent dye. A common assay is the enzyme-based ELISA (Enzyme-Linked ImmunoSorbent Assay), which is generally a labor-intensive and time-consuming process. Spectrophotometric and spectroscopic techniques often allow much quicker detections, but with limited or inadequate sensitivity and specificity. In recent years, optical biosensor technologies including surface plasmon resonance (SPR) and resonant waveguide (RWG) have gained popularity because of the significant improvement of both detection specificity and sensitivity over conventional techniques.

In embodiments the disclosure provides methods for using biosensors to detect the presence of biomacromolecules and evaluating their biological functions in a cellular environment. The biosensors, including, for example, an impedance-based electric biosensor, an evanescent wave-based optical biosensor, or like sensors, are capable of detecting cellular activities in a label-free and manipulation-free format. In addition, applying biosensors to the detection of biomacromolecules provides a real-time readout of the function of a target molecule, and simultaneously allows a definitive functional assessment of the target molecule and an accurate measurement of its effective concentration. Using this approach, detection with high specificity and sensitivity can be achieved because the contributions from nonspecific bindings become insignificant. Nonspecific binding has historically been problematic with affinity assays. The disclosure provides an excellent platform for, for example, biopharmaceutical screening, medical diagnostics, and like applications.

### Biosensor Technologies

Biosensors comprise specific transducers for converting a molecular recognition event into a quantifiable signal. Based on the nature of transducers, they can be categorized into different types of biosensors, such as calorimetric, acoustic, electrochemical, magnetic transducers, optical biosensors, or like sensors. Biosensors have realized widespread uses in examining molecular recognition or interactions in a label-free manner. Typically, a biological material (e.g., ligands, functional proteins, or antibodies) is contacted with the surface of a biosensor to form a biological layer. The interaction between a target analyte and the layer of biological material produces a change in a physical property of the transducer. Such changes can be detected by the transducer and used to directly quantify the binding of target molecules in a sample. Several types of biosensor technologies, primarily impedance-based electrical biosensors and evanescent wave-based optical biosensors, have recently been used to examine certain cellular activities under physiologic conditions.

### Impedance-Based Cell Assays

Electric impedance biosensors measure the changes in complex impedance (delta Z or dZ) of a cell layer that occur in response to stimulation. Cells are seeded onto a substrate that contains electrodes. The system applies small voltages to these electrodes at, for example, 24 different measurement frequencies, once every 2 seconds. At low frequencies, these voltages induce extracellular currents that pass around individual cells in the layer. At high frequencies, they induce transcellular currents that penetrate the cellular membrane. The ratio of the applied voltage to the measured current for each sample is its impedance (Z) as described by Ohm's law. When cells are exposed to a stimulus, such as a receptor ligand, signal transduction events are activated that lead to complex cellular events such as modulation of the actin cytoskeleton that cause, for example, changes in cell adherence, cell shape and volume, cell-to-cell interaction, and like changes. These cellular changes individually or collectively affect the flow of extracellular and transcellular current, and therefore, affect the magnitude and characteristics of the measured impedance.

### Evanescent Wave-Based Cell Assays

During the past several decades, a variety of optical biosensors have been developed including, for example, surface plasmon resonance (SPR), resonant waveguide grating (RWG), and resonant mirrors. A photonic crystal biosensor is an RWG type biosensor. Among them, SPR and RWG are the most popular ones. Both technologies exploit evanescent waves to characterize molecular interactions or alterations of a biological layer at or near the sensor surface. The evanescent-wave is an electromagnetic field, created by the total internal reflection of light at a solution-surface interface, which typically extends a short distance, for example, about several hundreds of nanometers from the biosensor's surface into the solution with a characteristic depth, termed the penetration depth or the sensing volume.

SPR relies on a prism to direct a wedge of polarized light, covering a range of incident angles, into a planar glass substrate bearing an electrically conducting metallic film (e.g., gold) to excite surface plasmons. The resultant evanescent wave interacts with, and is absorbed by the free electron clouds in the gold layer, generating electron charge density waves (i.e., surface plasmons) and causing a reduction in the intensity of the reflected light. The resonance angle at which this intensity minimum occurs is a function of the refractive index of the solution close to the gold layer on the opposing face of the sensor surface. In contrast, RWG biosensor utilizes the resonant coupling of light into a waveguide by means of a diffraction grating. A polarized light having a range of incident wavelengths is used to directly illuminate the waveguide; light at specific wavelengths is coupled into and propagate along the waveguide. The resonance wavelength at which a maximum in-coupling efficiency is achieved is a function of the local refractive index at or near the biosensor surface.

For cell-based assays, the live-cells rather than isolated receptors, are contacted with or brought to interact with the surface of a biosensor, generally via culturing. The cell adhesion can be mediated through three types of contacts: focal contacts, close contacts, and extracellular matrix (ECM) contacts. Each contact has its own characteristic separation distance from the surface. It is known that most of intracellular bio-macromolecules are well organized by the matrices of filament networks, and their location is highly regulated so that the cells can, for example, achieve specific and effective protein interactions, spatially separate protein activation and deactivation mechanisms, and determine specific cell functions and responses. Upon stimulation, there is often a significant relocation of cellular proteins, leading to a dynamic, directional, and directed mass redistribution, which is collectively referred to as dynamic mass redistribution (DMR). DMR can be detected by optical biosensors when it occurs within the sensing volume. The resultant DMR can be a unique physiological signal of live cells, which signal can be useful for, for example, monitoring receptor activation, studying the systems cell biology of a receptor, examining the systems cell pharmacology of a drug candidate, and like applications. The biosensor-based cell assay methodologies of the disclosure can be applicable to broad ranges of cells, as well as cellular targets including GPCR, receptor tyrosine kinases, ion channels, kinases, and like targets.

### Functional Mapping of Antibodies Against a Cell Surface Protein

In embodiments, the disclosure provides methods to functionally map an antibody against a specific cell surface target in a cellular environment using a biosensor. In embodiments, the functional mapping of antibodies can be achieved and is predicated upon the impact of antibodies on the biosensor signatures, which impact can be mediated through the activation of a cell target. The target can be activated directly by its ligand, or transactivated through a stimulus that activates a protein or pathway upstream of the specific target. In embodiments, the biosensor selected can be an electric impedance-based biosensor or an evanescent wave-based biosensor, such as surface plasmon resonance and resonant waveguide grating biosensor. The cells are adhered to or immobilized on the sensor surface, for example, through culturing to a desired or preferred confluency. Confluencies can depend on, for example, the cell type(s), the culture conditions, such as the time, the temperature, nutrient levels, the substrate, and like considerations.

In embodiments, the capabilities of the disclosed method were demonstrated by detecting the presence of and evaluating the function(s) of monoclonal antibodies of the human Epidermal Growth Factor receptor (EGFR) of A431 cells (i.e., a human epithelial carcinoma cell line). A431 cells were grown in a 96-well or 384-well Epic® plate until confluent. The cells were then incubated in serum-free media overnight and washed with HBSS (Hanks Balanced Salt Solution with 20 mM HEPES) buffer. The resulting A431 cells were then incubated with various concentrations of anti-EGFR antibody for three hours at a selected temperature before assays. The EGFR was then activated with EGF or methyl-β-cyclodextrin and the resultant DMR signals were then recorded.

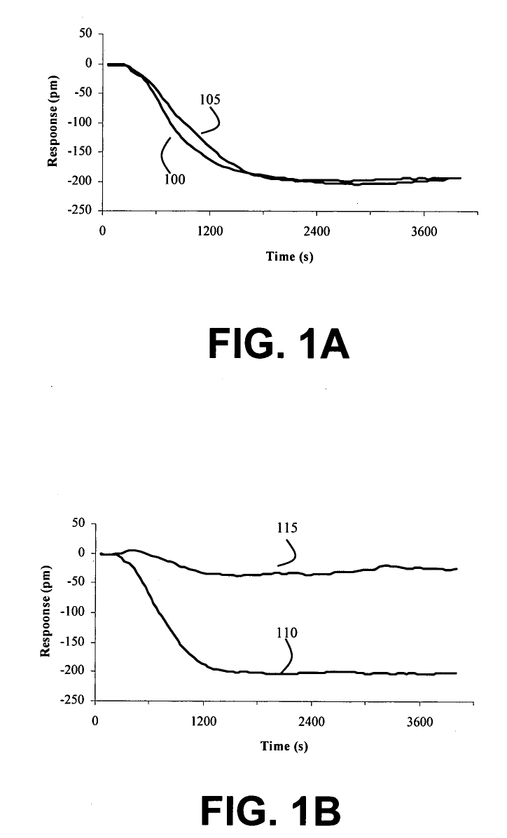

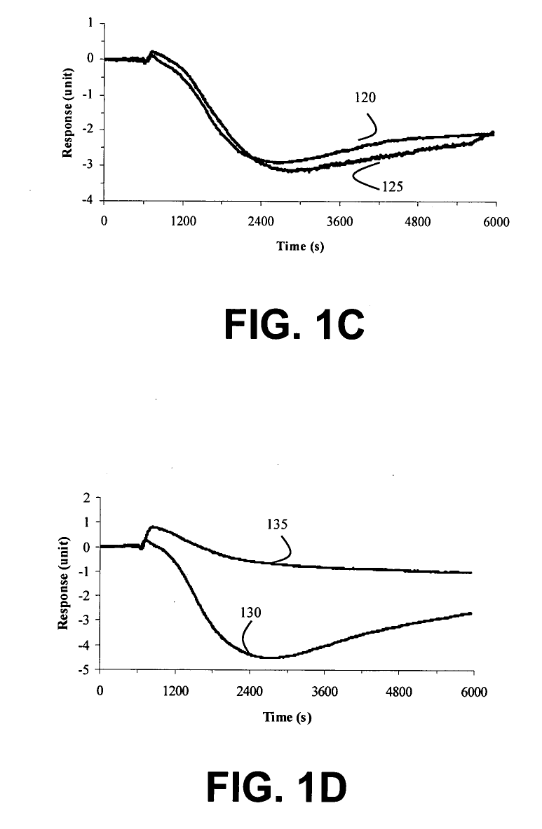

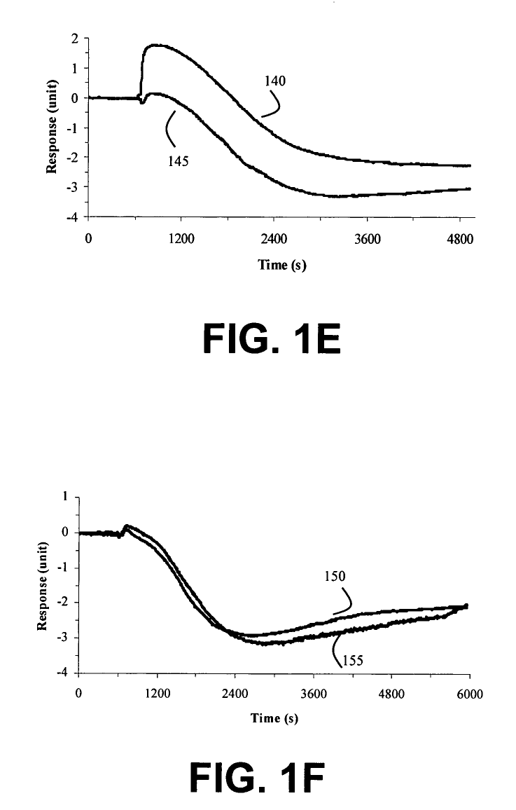

Anti-EGFR (clone R1) was previously reported to recognize extracellular domain II of EGFR and has no effect on EGF binding to EGFR (H. C. Gooi, et al., Biosci. Reports, 1985, 5, 83-94). Consequently, this antibody did not display any detectable inhibition on EGF-induced cellular responses with varying concentrations (FIG. 1C, Table 1). The inhibitory function of other monoclonal anti-EGFRs, such as clone 2E9 and clone 29.1, were also assessed using the Epic® cell based assay methods of the disclosure. The observed results, as shown in Table 1 in Example 1 and FIG. 1, were consistent with literature results that were determined by alternative analytical means.

Referring to the Figures, FIG. 1A illustrates real-time kinetic responses of quiescent A431 cells induced by 32 nM EGF against anti-EGFR (29.1). The antibody was used to pre-treat the A431 cells, and the kinetic profiles shown are for before- and after-stimulation, respectively, with EGF. The concentration of anti-EGFR (29.1) was 200 nM, 105 and was compared to a control at 0 nM, 100. Anti-EGFR (29.1) has no little or no effect, or no inhibition on the cellular response of quiescent A431 cells induced by 32 nM of EGF.

FIG. 1B illustrates real-time kinetic responses of quiescent A431 cells induced by 32 nM EGF against Anti-EGFR (2E9). The antibody was used to pre-treat the A431 cells, and the kinetic profiles shown are for before- and after-stimulation, respectively, with EGF. The concentration of anti-EGFR (2E9) was 133 nM, 115, and was compared with a control at 0 nM, 110. Anti-EGFR (2E9) attenuates the cellular response of quiescent A431 cells induced by 32 nM of EGF. Both FIG. 1A and FIG. 1B were obtained using Corning® Epic™ wavelength interrogation system. The unit reported is in wavelength shift in terms of picometer. 100 pm is approximately equivalent to 1 unit as measured using Corning® Epic™ angular interrogation system, as reported in FIG. 1C to FIG. 1F.

FIG. 1C illustrates real-time kinetic responses of quiescent A431 cells induced by 32 nM against Anti-EGFR (R1). The antibody was used to pre-treat the A431 cells, and the kinetic profiles shown are for before- and after-stimulation, respectively, with EGF. The concentration of anti-EGFR (R1) was 267 nM, 125, and was compared with a control at 0 nM, 120. Anti-EGFR (R1) has no or little inhibition effects on the cellular response of quiescent A431 cells induced by 32 nM of EGF.

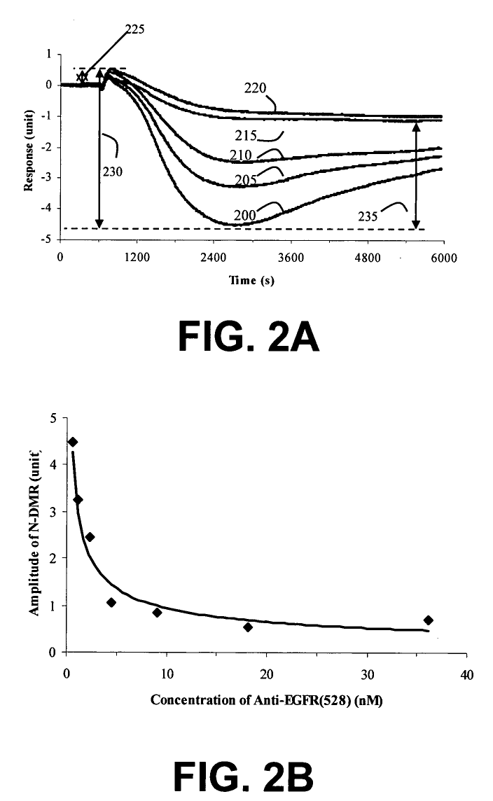

FIG. 1D illustrates real-time kinetic responses of quiescent A431 cells induced by 32 nM EGF against anti-EGFR (528). The antibody was used to pre-treat the A431 cells, and the kinetic profiles shown are for before- and after-stimulation, respectively, with EGF. A more comprehensive concentration range is provided and illustrated below in FIGS. 2A and 2B. The concentration of anti-EGFR (528) was 36.2 nM, 135, and was compared with a control at 0 nM, 130. Anti-EGFR (528) has inhibition effects on the cellular response of quiescent A431 cells induced by 32 nM of EGF.

FIG. 1E illustrates real-time kinetic responses of quiescent A431 cells induced by 32 nM EGF against Anti-EGFR (clone C11). The concentration of anti-EGFR (clone C11) was 40 nM, 145, and was compared with a control at 0 nM, 140. Anti-EGFR (C11) had inhibition effects on the cellular response of quiescent A431 cells induced by 32 nM of EGF. The antibody was used to pre-treat the A431 cells, and the kinetic profiles shown are for before- and after-stimulation, respectively, with EGF.

FIG. 1F illustrates real-time kinetic responses of quiescent A431 cells induced by 32 nM EGF against anti-Her2 (clone 9G6). The concentration of anti-Her2 (clone 9G6) was 267 nM, 155, and was compared with a control at 0 nM, 150. Anti-Her2 (9G6) had no or little inhibition effect on the cellular response of quiescent A431 cells induced by 32 nM of EGF. The antibody was used to pre-treat the A431 cells, and the kinetic profiles shown are for before- and after-stimulation, respectively, with EGF.

EGFR regulates many cellular process including proliferation, motility, and differentiation. Monoclonal antibodies directed against the EGFR can modulate ligand (EGF)-induced receptor activation and downstream signaling by either blocking the binding of EGF to EGFR, or obstructing the unfolding of EGFR and preventing the formation of the active form of EGFR. Anti-EGFR (clone 528) has been shown to bind to the extracellular domain III of EGFR and block the entry to EGF to its binding site on EGFR. As a result, this monoclonal antibody is capable of inhibiting the EGF-induced cellular responses. In embodiments of the disclosure, such inhibition was detected, as illustrated by the decreasing level of N-DMR (FIG. 2A) with the increasing concentrations of anti-EGFR (528). A K_{d} value could be estimated at sub-nanomolar (nM) level from the inhibition curve (FIG. 2B) which was consistent with the reported value (est. K_{d} 0.6 to 3 nM). The highly inhibitory effect of this type of anti-EGFR allows the detection of the presence of such antibodies at a sub-nanomolar concentration possibly as low as 0.1 nM using Epic® cell-based assay technology.

FIG. 2A illustrates exemplary dose-dependent real-time kinetic responses of quiescent A431 cells induced by 32 nM of EGF, where the cells were pretreated with anti-EGFR (528) at different doses. FIG. 2B shows normalized amplitudes of N-DMRs plotted as a function of the concentration of anti-EGFR (528), in embodiments of the disclosure. In FIG. 2A the concentrations of monoclonal anti-EGFR (clone 528) are indicated by the accompanying reference numerals as follows: 0.57 nM, 200; 1.13 nM, 205; 2.27 nM, 210; 4.53 nM, 215; and 9.06 nM, 220. Referring to the EGF-induced DMR signal, reference numeral 225 indicates the observed P-DMR event and its amplitude, reference numeral 230 indicates the observed N-DMR event and its amplitude, and reference numeral 235 indicates the observed recovery phase P-DMR (RP-DMR) event and its amplitude. Anti-EGFR (528) inhibits cellular responses of quiescent A431 cells induced by 32 nM of EGF.

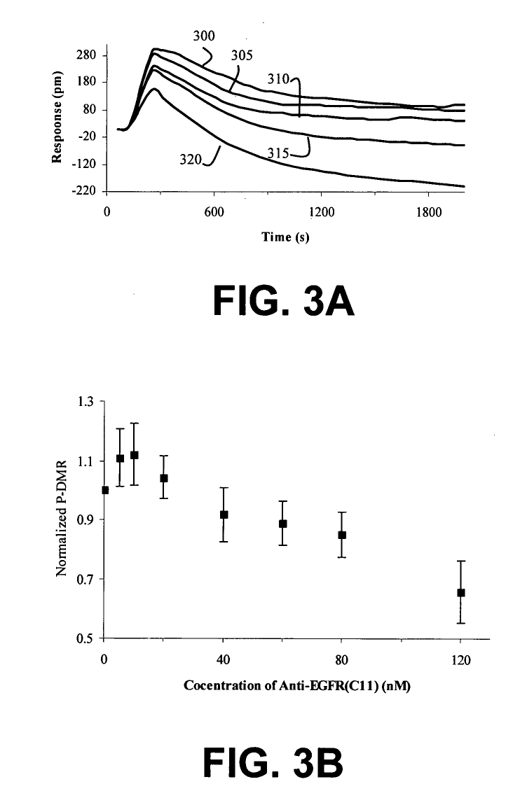

FIG. 3A shows dose-dependent real-time kinetic responses of quiescent A431 cells induced by 5 mM of methyl-β-cyclodextrin against varying concentrations of monoclonal anti-EGFR (clone C11). FIG. 3B shows normalized amplitudes of P-DMRs as a function of the concentration of anti-EGFR (C11). Concentrations of monoclonal anti-EGFR (C11) are indicated by the accompanying reference numerals as follows: 120 nM, 320; 80 nM, 315; 40 nM, 310; 20 nM, 305; and control 0 nM, 300. Anti-EGFR (C11) appears to inhibit the cellular response of quiescent A431 cells induced by 5 mM of methyl-β-cyclodextrin.

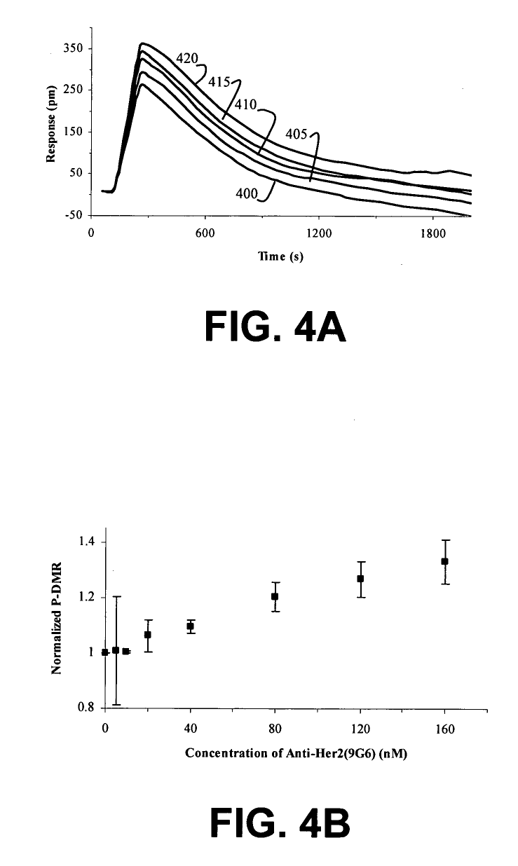

FIG. 4A shows dose-dependent real-time kinetic responses of quiescent A431 cells induced by 5 mM of methyl-β-cyclodextrin against varying concentrations of monoclonal anti-Her2 (clone 9G6). FIG. 4B shows normalized amplitudes of P-DMRs as a function of the corresponding concentration of anti-Her2 (9G6). The concentrations of monoclonal anti-Her2 (9G6) are indicated by the accompanying reference numerals 40 nM, 405; 80 nM, 410; 120 nM, 415; 160 nM, 420; and control 0 nM, 400. Anti-Her2 (9G6) appears not to inhibit but rather appears to stimulate the cellular response of quiescent A431 cells induced by methyl-β-cyclodextrin.

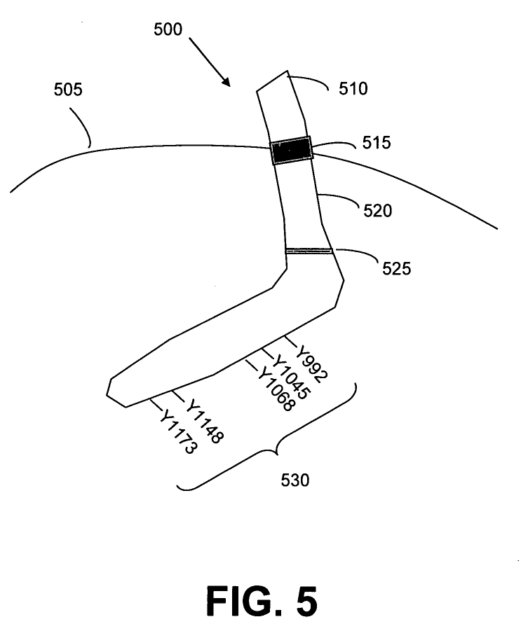

FIG. 5 is a schematic representation of an Epidermal Growth Factor receptor (EGFR) 500 showing major domains and potential surface and intracellular points of antibody interaction. A transmembrane receptor tyrosine kinase transmembrane EGFR 500, hosted by a cell membrane 505, provides domains having potential interaction sites including a cysteine-rich extracellular domain 510 (ligand binding site), a transmembrane domain 515, a kinase domain 520, an internalization domain 525, and a cyctoplasmic domain 530 (includes autophosphorylated tyrosine residues).

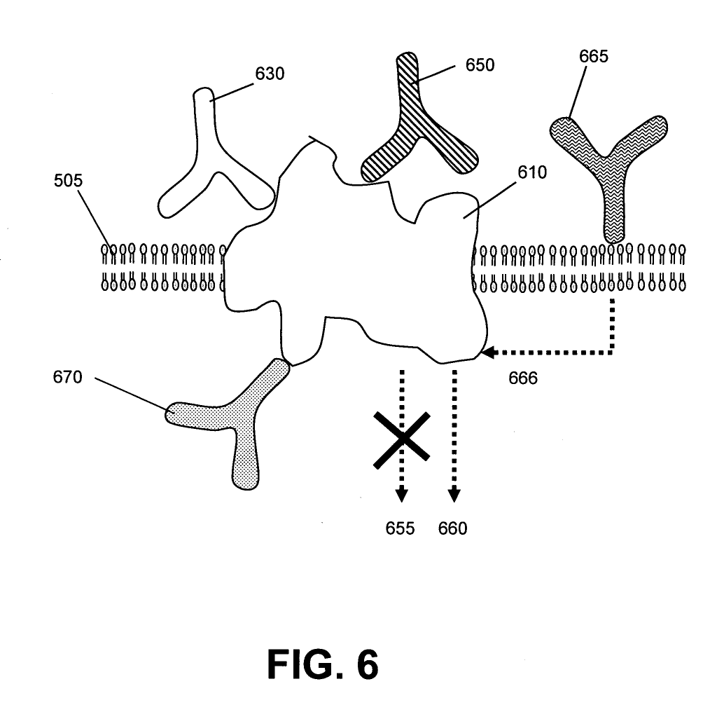

FIG. 6 is a schematic representation of exemplary antibody interactions and outcomes with a target receptor 610, such as epidermal growth factor receptor (EGFR). In embodiments, a cell membrane 505 having a receptor, such as a transmembrane receptor 610 (e.g., EGFR), can bind with an antibody 630. Such a binding event can result in binding only. In contrast, a different antibody 650 binding to receptor 610 at a different receptor epitope can result in, for example, inhibition or blocking 655 or activation 660 of an intracellular pathway. Alternatively or additionally, an antibody 665 can indirectly interact with the receptor by, for example, a remote transactivating marker (not shown), such as a G protein-coupled receptor ligand that transactivates epidermal growth factor receptor, by generating an indirect signal or message 666 which in-turn can similarly produce inhibition 655 or stimulation 660 of an intracellular pathway. Such antibody modulation affects, such as pathway inhibition or stimulation, can be detected and measured in embodiments with methods of the disclosure.

Anti-EGFR can also influence ligand-independent activation. In embodiments of the disclosure, methyl-β-cyclodextrin was used to transactivate EGFR in the absence of its native ligand EGF. It is believed that methyl-β-cyclodextrin extracts cholesterol from the cell membrane, disrupts the lipid raft, and causes a rearrangement of EGFR in the membrane to form the large receptor cluster. Such clustering consequently triggers the activation of EGFR and its downstream signaling. Therefore, the ligand-independent activation or transactivation of EGFR provides a method to assess the functional role of anti-EGFR as a modulator of the oligomerization of EGFR in the absence of EGF. Anti-EGFR (clone C11) was derived from a partial peptide sequence of the extracellular domain IV of EGFR. Workers in the field have speculated that the domain IV may be involved in EGFR dimerization through domain-domain interaction with another molecule of EGFR. (See for example, Jorissen R. N., et al., “Epidermal growth factor receptor: mechanisms of activation and signaling,” Experimental Cell Research, 2003; 284, 31-53.)

It is conceivable that the binding of anti-EGFR (C11) to an EGFR could subsequently block the access of its domain IV to another EGFR, to prevent possible dimerization and inhibit subsequent EGFR activation. Such effects on cellular responses were detected using the Epic® cell based assay (FIG. 3), as an anticipated inhibitory effect on the amplitudes of P-DMR as a function of the anti-EGFR (C11) concentration. Similarly, the stimulating effect of anti-Her2 (clone 9G6) on transactivated cellular responses (FIG. 4) suggests that anti-Her2 (9G6) may facilitate the dimerization of EGFR. Her2 is another form of EGFR (Her1) and it tends to form heterodimers with EGFR. Thus, anti-Her2 may well recognize and stabilize an EGFR in an oligomeric form and consequently promote the activation of EGFR. The precise cellular functions of both anti-EGFR (C11) and anti-Her2 (9G6) were previously unknown.

The Epic® cell-based assay apparatus and methodology can detect and examine other anti-EGFR functions, such as directly triggering a specific phosphorylation pattern and leading to specific cell signaling pathways, or mediating the interaction of EGFR and its signaling cascades with other classes of receptors (e.g., GPCRs).

### Functional Mapping of Antibodies Against an Intracellular Target

In embodiments, the disclosure provides methods to map the function of antibodies against a specific intracellular target using biosensors in a live-cell environment. In embodiments, the functional mapping of antibodies can be demonstrated based on the impact of antibodies on the biosensor signatures mediated through the activation of a target. The target can be, for example, activated directly by any of its ligands, or transactivated through a stimulus that activates a protein or pathway upstream of the specific target. The biosensor can be, for example, an electric impedance-based biosensor or an evanescent wave-based biosensor, such as a surface plasmon resonance or resonant waveguide grating biosensor. The cells adhere to the sensor surface, primarily through culturing. The uptake of an antibody into a cell can be achieved by, for example, using conventional protein delivery methods, or using a reverse protein delivery, see for example U.S. Pat. No. 7,105,347.

### Mass Redistribution Cell Assay Technology (MRCAT)

In commonly-owned, copending PCT application, entitled “Label-Free Biosensors and Cells,” Y. Fang et al., PCT App. No. PCT/US2006/013539 (Pub. No. WO 2006/108183), published Dec. 10, 2006, there is disclosed a non-invasive and manipulation-free cell assay methodology referred to as Mass Redistribution Cell Assay Technology (MRCAT). MRCAT uses an optical biosensor, particularly a resonant waveguide grating (RWG) biosensor, to monitor the ligand-induced dynamic mass redistribution within the bottom-most portion of adherent cells. The DMR signal obtained represents an integrated cellular response, which resulted from a ligand-induced dynamic, directed, and directional redistribution of cellular targets or molecular assemblies. MRCAT permits the study of cell activities, such as signaling and its network interactions, and can also enable high throughput screening of ligand candidate compounds against endogenous receptors or over-expressed receptors in engineered cells or cell lines.

Since the optical biosensor exploits a typical short evanescent wave to probe the cellular activities and signaling, the cells are generally required to be brought into contact with the surface of a biosensor. This can be achieved by several methods. For adherent cells, the cells can be directly cultured onto the surface of a biosensor. For weakly adherent cells, cells can be directly cultured onto the surface of a biosensor whose surface consists of a material supporting the anchorage of the cells (e.g., extracellular matrix materials such as fibronectin, lamin, collagen, gelatin; or polymeric materials such as polylysines). For suspension cells, the cells can be brought into contact with the surface of a biosensor whose surface consists of reactive moieties (such as amine-reactive polymer to interact with the cell surface proteins and thus couple the cells to the surface, or antibodies to interact specifically with the cell surface proteins and thus anchor the cells onto the sensor surface).

MRCAT starts with the interaction or contact of cells with the surface of a biosensor. Typically, cells are cultured directly onto the surface of a RWG biosensor. Exogenous signals can mediate the activation of specific cell signaling, in many instances resulting in dynamic redistribution of cellular contents equivalent to dynamic mass redistribution (DMR). If signaling occurs within the sensing volume (i.e., the penetration depth of the evanescent wave) then the DMR can be detected and monitored in real time by a RWG biosensor. Because of its ability for multi-parameter measurements, the biosensor can provide information rich content for cell sensing. These parameters include the angular shift (the most common output), the intensity, the peak-width-at-half-maximum (PWHM), the area, and the shape of the resonant peaks. The position-sensitive responses across an entire sensor can provide additional useful information regarding to the uniformity of cell states, for example, density and adhesion degree, and the homogeneity of cell responses for cells located at distinct locations across the entire sensor.

The DMR signals can yield valuable information regarding novel physiological responses of living cells. Because of the exponential decay of the evanescence wave tail penetrating into the cell layer, a target or complex of a certain mass contributes more to the overall response when the target or complex is closer to the sensor surface as compared to when it is further from the sensor surface. Furthermore, the relocation of a target or complex towards the sensor surface results in an increase in signal, whereas the relocation of a target or complex that moves away from the sensor surface leads to a decrease in signal. The DMR signals mediated through a particular target were found to depend on the cell status, such as degree of adhesion, and cell states, such as proliferating and quiescent states.

Because of the short sensing volume of commonly available optical biosensors, such as RWG and SPR, the biosensor-based cell assays depend on close proximity of cells with the sensor surface. In addition, attachment of cells, growth of cells, or both, can be significant factors in the success of the present cell-based biosensor and its assay methods. In embodiments, the modified biosensor surfaces of the disclosure can be biocompatible with and support the attachment and growth of a wide variety of cell lines. In embodiments, cells adhered to the biosensor surface can withstand manipulations such as washing and reagent dispensing. Methods for attaching cells to a biosensor surface are disclosed, for example, in copending provisional application U.S. Ser. No. 60/904,129, to Fang, Y., et al., entitled “Surfaces and Methods for Biosensor Cellular Assays,” filed Feb. 28, 2007.

An example of a commercial instrument embodying the resonance wavelength method is the Corning® Epic® system (www.corning.com/lifesciences), which includes an RWG detector having, for example, a temperature-controlled environment and an optional liquid handling system.

Optical biosensor measurements—In an angular interrogation system, a polarized light, covering a range of incident angles, is used to directly illuminate the waveguide; light at specific angles is coupled into and propagates along the waveguide. The resonance angle at which a maximum in-coupling efficiency is achieved is a function of the local refractive index at or near the sensor surface. When target molecules in a sample bind to a cellular target in a live-cell system and trigger a cellular response within the bottom portion of the layer of the cell system or the biological systems, the resonance angle shifts.

A Corning Inc.® Epic® angular interrogation system with transverse magnetic or p-polarized TM₀ mode as described in, for example, U.S. Pat. Pub. Nos. US-2004-0263841 and US-2005-0236554, U.S. patent application Ser. No. 11/019,439, filed Dec. 21, 2004, was used. After culturing the cells were washed twice and maintained with 1×HBSS (1× regular Hank's balanced salt solution, 20 mM HEPES buffer, pH 7.0). Afterwards, the sensor microplate containing cells was placed into the optical system, and the cell responses were recorded before and after addition of a solution. All studies were carried out at room temperature with the lid of the microplate “on” except for a short period of time (about seconds) when the solution was introduced, in order to minimize the effect of temperature fluctuation and evaporative cooling.

For cell-based assays of the present disclosure, live-cells can be contacted with a suitable surface of a biosensor, for example, via culturing. The cell adhesion can be mediated through, for example, three types of contacts: focal contacts, close contacts, or extracellular matrix (ECM) contacts. Each type of contact has its own characteristic separation distance from the surface. As a result, cell plasma membranes are about 10 to about 100 nm away from the substrate surface, so that optical biosensors of relatively short penetration depths are still able to sense the bottom portion of the cells proximate to the biosensor surface. A phenomenon that is common to many stimuli-induced cell responses is dynamic relocation or rearrangement of certain cellular contents; some of which can occur within the bottom portion of cells proximate to the biosensor surface. Dynamic relocation or rearrangement of cellular contents can include, for example, changes in adhesion degree, membrane ruffling, recruiting intracellular proteins to activated receptors at or near a cell's surface, receptor endocytosis, and like phenomena. A change in cellular contents within the sensing volume leads to an alteration in local refractive index near the sensor surface, which manifests itself as an optical signal from the biosensor.

Based on the configuration of the biosensors used and the uniqueness of cell properties, the penetration depth of the TM₀ mode for Corning® Epic® RWG biosensor microplates is, for example, about 150 nm. Such relatively short penetration depth or sensing volume is common to most types of label-free optical biosensor technologies including conventional SPR and RWG (e.g., photonic crystal biosensor), so that the disclosure is applicable to other optical biosensor-based cell sensing.

Theoretical analysis suggests that the detected signal, in terms of wavelength or angular shifts, is primarily sensitive to the vertical mass redistribution. Because of its dynamic nature, it is also referred to as a dynamic mass redistribution (DMR) signal. Beside the DMR signal, the biosensor is also capable of detecting horizontal (i.e., parallel to the sensor surface) redistribution of cellular contents. Theoretical analysis, based on the zigzag theory, shows that any changes in the shape of a resonant peak are mainly due to ligand-induced inhomogeneous redistribution of cellular contents parallel to the sensor surface (see Fang, Y., et al., “Resonant Waveguide Grating Biosensor for Live Cell Sensing,” Biophys. J, 91, 1925-1940 (2006)). In addition, the DMR signal is a sum of all redistribution events within the sensing volume. This suggests that whole live-cell sensing with the biosensor methods of the disclosure are distinct from the conventional affinity-based assays, which directly measure the amount of analyte binding to the immobilized receptors.

### EXAMPLES

The following examples serve to more fully describe the manner of using the above-described disclosure, and to set forth the best modes contemplated for carrying out various aspects of the disclosure. It is understood that these examples in no way serve to limit the true scope of this disclosure, but rather are presented for illustrative purposes.

### Example 1

### Functional Assessment of Anti-EGFR Antibodies Using Angular Interrogation Resonant Waveguide Grating Biosensor

Epidermal growth factor (EGF) receptor belongs to the receptor tyrosine kinase (RTK) family and is expressed in virtually all organs of mammals. EGF receptors play a complex role in cell growth and differentiation, as well as in the progression of tumors. EGFR is also a critical downstream element of other signaling systems, and crosstalks with other receptors such as mitogenic G protein-coupled receptors (GPCRs).

The engagement of EGFR by its cognate ligand results in the generation of a number of intracellular signals. Binding of EGF mediates receptor dimerization and subsequent autophosphorylation of the receptor on tyrosine residues of the cytoplasmic domain. A multitude of signaling proteins are then recruited to the activated receptors through phosphotyrosine-specific recognition motifs. This modular association of signaling molecules with the receptor results in activation of these signaling molecules, which, in turn, activate and trigger a number of downstream signals. One particular pathway that promotes gene expression and ultimately cell proliferation involves the signaling proteins Shc, Grb2, Sos, Ras, Raf, MEK, ERK and ERK/MAPK, and is known as the Ras/MAPK pathway.

Antibodies are a class of protein that are found in body fluid and are used by the immune system to neutralize the invasion of the foreign molecules such as presented by, for example, bacteria and viruses. Each individual antibody possesses a degree of specificity for recognizing and binding to a specific epitope of the target molecules. A variety of anti-EGF receptor monoclonal antibodies have been developed by raising the hybridomas against a selected region of EGF receptor, either extracellular domain or cyctoplasmic domain. Some of these antibodies are known to have effects on ligand binding to the EGFR, others are recognized by their abilities to impact EGFR endocytosis, trafficking, and degradation. Available methods for assessment of anti-EGFR antibody functionality include, for example, lengthy biochemical studies involving, for example, fluorescent or radioisotopic labeling schemes. In embodiments, the present disclosure assesses antibody functionality using biosensor-based cell assay technologies, specifically MRCAT, to directly assess the biological functions of antibodies in a cellular environment with a label-free and optionally multiplex format.

### Materials and Methods

Materials: EGF and methyl-β-cyclodextrin were purchased from Sigma Chemical Co. (St. Louis, Mo.). Corning® Epic® 96-well biosensor microplates were obtained from Corning Inc. (Corning, N.Y.), and cleaned by exposure to high intensity UV light (UVO-cleaner, Jelight Company Inc., Laguna Hills, Calif.) for 6 minutes before use. Anti-EGFR including clone 528, R1, and 9G6 were purchased from Santa Cruz Biotechnology, Inc. (Santa Cruz, Calif.). Anti-EGFR (2E9) was purchased from Abcam Inc. (Cambridge, Mass.). Anti-EGFR (29.1) was purchased from Sigma Chemical Co. (St. Louis, Mo.). Anti-EGFR (C11) was purchased from Chemicon International (Temecula, Calif.).

Angular interrogation resonant waveguide grating (RWG) biosensor: The angular interrogation RWG biosensor detection system was previously disclosed in U.S. patent application Ser. No. 10/602,304, filed Jun. 24, 2003 having publication no. US-2004-0263841, published Dec. 30, 2004, and U.S. patent application Ser. No. 11/019,439, filed Dec. 21, 2004, all incorporated by reference at least for aspects relating to biosensors and their uses. Such system provides a launch system for generating an array of light beams such that each illuminates an RWG sensor with a dimension of about 200 μm×3,000 μm and a receiver system for receiving all responses, as indicated by the angles of the light beams reflected from these sensors. This system allows, for example, up to 7×7 well sensors to be simultaneously sampled at a rate of 3 seconds. Unlike a SPR that is fine-tuned for affinity screening against the surface-bound “receptors” and generally uses a parallel flow chamber to continuously deliver bio-assay solution, the current system remains relatively static and optionally allows for the gentle introduction of solution(s) using an on-board liquid handling system during the assay, so that it minimizes the unwanted effect of fluid movements on the cells. Because of the unique design, each sensor gives rise to a resonant band which can be divided into multiple segments for data collection and analysis. The segments having no cells can serve as intra-well self-referencing areas to filter out any unwanted effects.

The RWG sensors are thermally sensitive, meaning that any difference in temperature between the compound solution and the cell medium could complicate the cell responses. To minimize or eliminate such effect, all solutions were typically equilibrated for about 3 hrs inside the temperature controlled detection system before applied to the cells. In addition, all studies were carried out at or near room temperature in order to minimize the effect of temperature fluctuation and evaporative cooling.

Cell culture and biosensor cell assays: Human epidermoid carcinoma A431 cells (American Type Cell Culture) were grown in Dulbecco's modified Eagle's medium (DMEM) supplemented with 10% fetal bovine serum (FBS), 4.5 g/liter glucose, 2 mM glutamine, and antibiotics. About 3 to about 7.5×10⁴ cells at passage 3 to 5 suspended in 200 microliters the DMEM medium containing 10% FBS were placed in each well of a 96-well microplate. Similarly, about 1 to about 2×10⁴ cells in 50 microliters the growth medium were placed in each well of a 384 well microplate. After cell seeding, the cells were cultured at 37° C. under air/5% CO₂ until about 95% confluency was reached (about 1-2 days). The confluent cells were washed with serum-free medium and incubated in the same medium at 37° C. under air/5% CO₂ for 20 hours. On the day of assay, the cells were washed with HBSS (Hanks Balanced Salt Solution with 20 mM HEPES) buffer. The resulting A431 cells were then incubated with various concentrations of anti-EGFR for two to three hours at a selected temperature before assays. The EGFR was activated with EGF or methyl-β-cyclodextrin and the resultant DMR signals were then recorded.

Statistical analysis: Unless specifically mentioned, duplicates were carried out for the measurement of each compound. The standard deviation was derived from these measurements (n=2). All dose-dependent responses were analyzed using non-linear regression with GraphPad Prism® software (from GraphPad Software).

### Results and Discussion

A large number of monoclonal or polyclonal antibodies have been developed against EGFR in the past 30 years. Some of them have been well characterized including their ability to inhibit EGF binding and affect the cellular function have been thoroughly examined, e.g., anti-EGFR (clone 528). This particular monoclonal antibody was employed to demonstrate the feasibility of using Epic® cell based assay technology to map the function of monoclonal antibodies on EGFR activation and downstream signaling pathway.

First, a series of concentrations of anti-EGFR (528) in HBSS assay buffer were allowed to incubate with quiescent A431 cells in a 96-well Epic® plate at room temperature for 3 hours in the angular interrogation RWG biosensor detection system to achieve an equilibrium, indicated by the stable baseline of each biosensor. The EGFR signaling was then initiated with the addition of a fixed concentration of EGF (32 nM or 64 nM) to each reaction and the cellular response of each was monitored and recorded for two hours.

The cellular responses, as manifested by the angular shift of the light beam, consist of three distinct, sequential phases: 1) a positive phase with increased signal (P-DMR) (225 in FIG. 2A); 2) a long decay phase with decreased signal (N-DMR) (230 in FIG. 2A); and 3) a recovery phase with increased, and then leveled-off signal (RP-DMR) (235 in FIG. 2A). Typically, the P-DMR is mainly related to recruitment of protein effectors to the activated EGFR or cell plasma membrane. The N-DMR is an overall result primarily of endocytosis of the receptors and morphological alteration of cells associated with cell attachment. The RP-DMR mainly corresponds to the process of a partial reattachment of cells.

The amplitudes of N-DMRs of clone 528, plotted against the concentration of anti-EGFR (528) showed a decreasing trend with the increasing concentration of anti-EGFR (528) (FIG. 2B), revealing an inhibitory effect of anti-EGFR (528) on the EGFR signaling. An IC₅₀ value could be estimated at sub-nanomolar level from the inhibition curve (FIG. 2B), which was consistent with the reported value (0.6 to 3 nM). See Kawamoto T, et al., “Growth stimulation of A431 cells by epidermal growth factor: identification of high-affinity receptors for epidermal growth factor by anti-receptor monoclonal antibody,” Proc. Natl. Acad. Sci. USA, 1983; 80, 1337-1341. Also, anti-EGFR (528) has been shown to bind to the extracellular domain III of EGFR and block the entry of EGF to its binding site on EGFR. Ibid. The strong inhibitory effect of this type of anti-EGFR allows the detection of the presence of such antibodies at a sub-nanomolar level such as at or below about 0.1 nM using the Epic® cell-based assay methodology of the disclosure.

Similarly, the inhibitory effects of anti-EGFRs (clone R1, clone 2E9, and clone 29.1) were assessed and the results were consistent with the alternative procedures reported in the literature (FIG. 1A to F, and Table 1). The clone C11 was also found to have an inhibitory effect on EGFR activation and signaling, whose function has not been previously fully understood nor clearly defined.

Table 1 below provides classifications of EGFR antibody function(s) based on Epic® cell-based assays. The Epic® cell-based assay methodology results were consistent with results obtained by alternative methods reported in the literature.

TABLE 1
Classification of EGFR antibody functionalities based
on Epic ® Optical Biosensor cell-based assays.

| Anti-EGFR | Targeted | Epic ® Cell | Literature | Figure |
|---|---|---|---|---|
| antibody▾ | domain▾ | Assay Result | Reference | Reference |
| 29.1 | Oligosac- | no inhibition | no inhibition⁽¹⁾ | 1A |
| | charide | | | |
| 2E9 | I | inhibition | inhibition⁽²⁾ | 1B |
| R1 | II | no inhibition | no inhibition⁽¹⁾ | 1C |
| 528 | III | inhibition | inhibition⁽³⁾ | 1D and |
| | | | | 2A |
| C11 | IV | inhibition | N.D.⁽⁴⁾ | 1E and |
| | | | | 3A |
| 9G6 | Her2 | no inhibition | N.D.⁽⁴⁾ | 1F and |
| | | | | 4A |

⁽¹⁾Gooi, H. C., et. al., “The carbohydrate specificities of the monoclonal antibodies” 29.1, 455 and “3C1B12 to the Epidermal Growth Factor receptor of A431 cells,” Biosci. Reports, 1985, 5: 83-94.
⁽²⁾Defize, L. H. K., et. al., “Signal transduction by Epidermal Growth factor occurs through the subclass of high affinity receptors,” J Cell Biol., 1989, 109: 2495-2507.
⁽³⁾Gill, G. H., et. al.,. “Monoclonal Anti-Epidermal Growth Factor receptor antibodies which are inhibitors of Epidermal Growth Factor binding and antagonists of Epidermal Growth Factor-stimulated tyrosine protein kinase activity,” J. Biol. Chem., 1984, 259(12): 7755-7760.
⁽⁴⁾N.D.—not determined.

### Example 2

### Functional Assessment of Anti-EGFR Antibodies Using Ligand-Independent and Label-Free Cell Assays Based on Wavelength Interrogation System

Previously it had been demonstrated that methyl-β-cyclodextrin is capable of extracting lipid cholesterol from cell membrane, inducing the rearrangement of lipid raft, and resulting clustering of the EGFR. See Lambert S., et al., “Ligand-independent activation of the EGFR by lipid raft disruption”. J. Investigative Dermatology, 2006; 126, 954-962. Consequently, this leads to the transactivation and downstream signaling of EGFR. By examining the effect of the antibody on EGFR transactivation, the functional role of anti-EGFR as a modulator of the oligomerization of EGFR trigged by methyl-β-cyclodextrin in the absence of EGF can be assessed. The Epic® label-free, wavelength interrogation system with transverse magnetic or p-polarized TM₀ mode (x-direction scan) was used in this study instead of the angular interrogation system used in the previous example.

### Materials and Methods

Wavelength interrogation system: The Epic® system is centered on RWG biosensors, which are integrated in standard SBS microtiter plates (primarily 384-well microplates). The surfaces of the sensors in the microplates are readily modified to enable direct coupling of receptors for affinity-based biochemical assays, or appropriate cell attachment and growth for cell-based assays.

The system can be standalone and can consist of a temperature-control unit, an optical detection unit, and an optional on-board liquid handling unit with robotics. The temperature-control unit is built-in to minimize temperature fluctuation if any. Inside the unit, there are two side-by-side stacks for holding both the sensor microplates and compound source plates. Once the temperature is stabilized, a sensor microplate is robotically transferred into the plate holder directly above the detection system, while a source plate is moved to an appropriate compartment so that it is readily addressable by the on-board liquid handling unit.

The detection unit is built around integrated fiber optics to measure the wavelength shift of the resonant waves due to the ligand-induced DMR in living-cells. A broadband white light source, generated through a fiber optic and a collimating lens at nominally normal incidence through the bottom of the microplate, is used to illuminate a small region of the grating surface. A detection fiber for recording the reflected light is bundled with the illumination fiber. A series of illumination/detection heads are arranged in a linear fashion, so that reflection spectra are collected from a subset of wells within the same column of a 384-well microplate at once. The whole plate is scanned by the illumination/detection heads so that each sensor can be addressed multiple times, and each column is addressed in sequence. The scanning can be continuous or discontinuous depending, for example, upon the assay formats selected. The wavelengths of the reflected light are collected and used for analysis.

For kinetic assays, a baseline response is recorded first for a given period of time. Afterwards, compound solutions are transferred into the sensor plate using the on-board liquid handling system, and the cell responses are then recorded for another period of time. Typically, the lid of the sensor microplates remains on most of the time throughout the assay, except for a brief period (e.g., about 2 min) when compounds are introduced. The plate lid can be handled automatically by robotics. Such kinetic measurements provide useful information for GPCR signaling and its networked interactions.

Cell culture and biosensor cell assays: Human epidermoid carcinoma A431 cells (American Type Cell Culture) were grown in Dulbecco's modified Eagle's medium (DMEM) supplemented with 10% fetal bovine serum (FBS), 4.5 g/liter glucose, 2 mM glutamine, and antibiotics. About 1.5 to about 2×10⁴ cells at passage 3 to 5 and suspended in 50 μl the DMEM medium containing 10% FBS, were placed in each well of a 384-well microplate. After cell seeding, the cells were cultured at 37° C. under air/5% CO₂ until about 95% confluency was reached (about 1-2 days). The confluent cells were washed with serum-free medium and incubated in the same medium at 37° C. under air/5% CO₂ for 20 hours. On the day of the assay, the cells were washed with HBSS (Hanks Balanced Salt Solution with 20 mM HEPES) buffer. The resulting A431 cells were then incubated with various concentrations of anti-EGFR for two to three hours at a selected temperature with a total volume of 40 microliters in each well before assays. The EGFR was activated with a solution of methyl-β-cyclodextrin (10 microliters, 25 mM) and then DMR signals were recorded. All studies were carried out at controlled temperature (28° C.).

### Results and Discussions

An alternative way to mediate the EGFR activation and signaling pathway is to facilitate or disrupt the receptor oligomerization of EGFR, with the assistance of monoclonal antibodies directed against the EGFR. In this study, two monoclonal antibodies anti-EGFR (clone C11) and anti-Her2 (clone 9G6) were evaluated by examining their effect on the EGFR transactivation in the presence of methyl-μ-cyclodextrin. In both cases, P-DMRs (the first increasing phase of the signals), induced by the addition of 5 mM of methyl-β-cyclodextrin were related to the EGFR activation. The amplitudes of those P-DMR signals were plotted against the concentrations of the antibody. Anti-EGFR (clone C11) showed a dose-dependent inhibitory effect (FIGS. 3A and 3B), whereas anti-EGFR (clone 9G6) showed a dose-dependent stimulating effect (FIGS. 4A and 4B).

The cellular functions of both anti-EGFR (C11) and anti-Her2 (9G6) have not been heretofore well defined. However, anti-EGFR (clone C11) has been known to bind to the extracellular domain IV of EGFR that may be involved in interacting with another molecule of EGFR for dimerization. Therefore, the inhibitory effect of anti-EGFR (C11) on EGFR activation may result from blocking the access of the domain IV of one EGFR to another EGFR. In contrast, anti-Her2 (9G6) was derived from Her2 receptor, another form of EGFR (Her1), which has tendency to form heterodimers with EGFR. Thus, anti-Her2 (9G6) may recognize and stabilize an EGFR in the oligomeric form and consequently promote the activation of EGFR.

### Example 3

### Functional Assessment of Anti-EGFR Antibodies with Prolonged Incubation Using Label-Free Cell Assays Based on Wavelength Interrogation System

One potential application of the disclosed methods is to screen neutralizing antibodies in a high throughput system (HTS) cell assay format. In embodiments, both short term and long term effects of the antibody on the target cells can be evaluated, and the cytotoxicity of the antibody during the incubation, which typically requires a long incubation of the antibody of choice with the targeting cells. In this study, the Epic® cell based assay was used to investigate the functions of antibodies with both long and short incubation times.

### Materials and Methods

Human epidermoid carcinoma A431 cells (American Type Cell Culture) were grown in Dulbecco's modified Eagle's medium (DMEM) supplemented with 10% fetal bovine serum (FBS), 4.5 g/liter glucose, 2 mM glutamine, and antibiotics. About 1.5 to about 2×10⁴ cells at passage 3 to 5 suspended in 50 microliters the DMEM medium containing 10% FBS were placed in each well of a 384-well microplate. After cell seeding, the cells were cultured at 37° C. under air/5% CO₂ until about 95% confluency was reached (about 1-2 days). The confluent cells were washed with serum-free medium and incubated with the desired antibody in the same medium at 37° C. under air/5% CO₂ for 20 hrs. On the day of the assay, each antibody solution in serum-free DMEM medium was exchanged with the same concentration of antibody in assay buffer (Hanks Balanced Salt Solution with 20 mM HEPES, 0.1% BSA) with a total volume of 40 microliters in each well before assays. After 2 hrs incubation at controlled temperature (28° C.) to allow the baseline to stabilize, the EGFR was activated with a solution of EGF (10 microliters) in assay buffer and DMR signals were then recorded.

### Results and Discussions

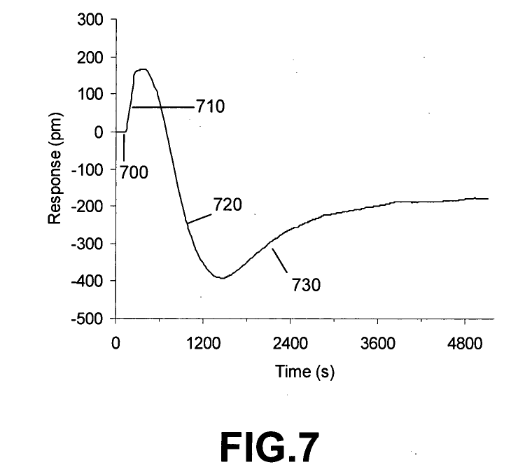

FIG. 7 shows a representation of the DMR signal of EGFR activation and signaling in A431 cells induced by 64 nM EGF. The kinetics consists of a basal response of cells before the addition of EGF (700); a positive phase with an increased signal (P-DMR)(710); a long decay phase with a decreased signal (N-DMR)(720); and a recovery phase with an increased, and then leveled-off signal (RP-DMR)(730).

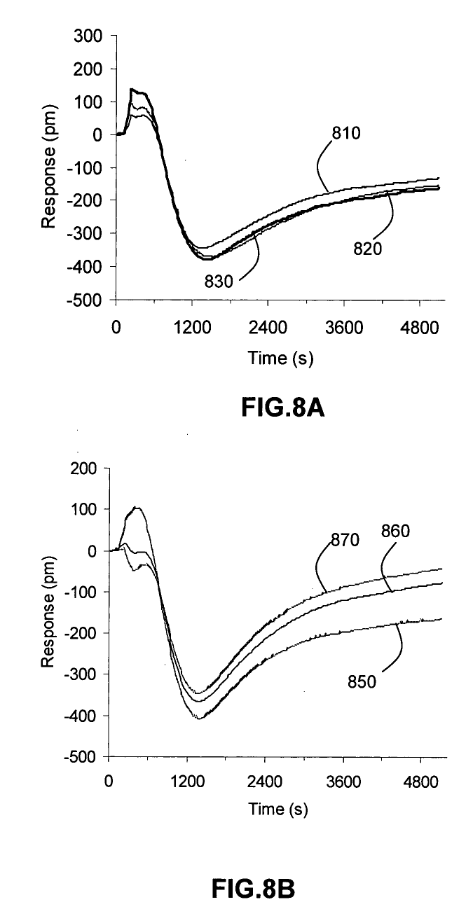

FIG. 8A shows dose-dependent real-time kinetic responses of quiescent A431 cells induced by 64 nM of EGF. The cells were incubated with anti-EGFR (clone R1) at 28° C. for 2 hours prior to induction. The observed curves were as follows: no anti-EGFR (clone R1)(810); 100 nM of anti-EGFR (clone R1)(820); and 200 nM of anti-EGFR (clone R1)(830).

FIG. 8B shows dose-dependent real-time kinetic responses of quiescent A431 cells induced by 64 nM of EGF. The cells were incubated with anti-EGFR (clone R1) at 37° C. for 24 hours prior to induction. The observed curves were as follows: no anti-EGFR (clone R1) (850); 100 nM of anti-EGFR (clone R1) (860); and 200 nM of anti-EGFR (clone R1)(870).

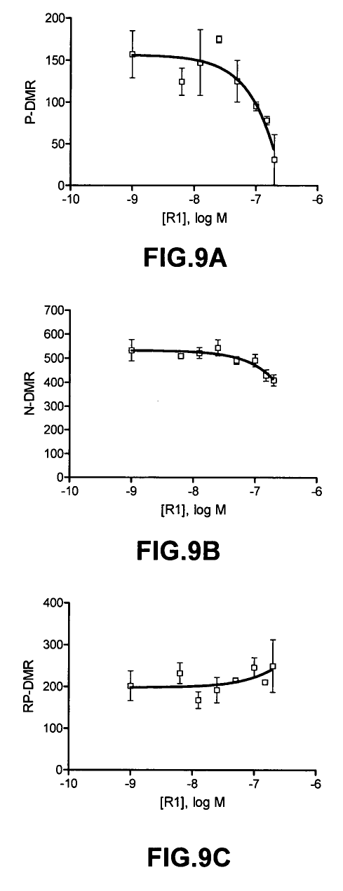

FIGS. 9A to 9C show the amplitudes of real-time kinetic responses of quiescent A431 cells induced by 64 nM of EGF as a function of the concentration of anti-EGFR (R1). The cells were incubated with anti-EGFR (R1) at 28° C. for 2 hours. The data were fitted with non-linear regression curve fit. FIG. 9A shows the cellular response based on P-DMRs. FIG. 9B shows the cellular responses based on N-DMRs. FIG. 9C shows the cellular responses based on RP-DMRs. The analysis is summarized following Table 2.

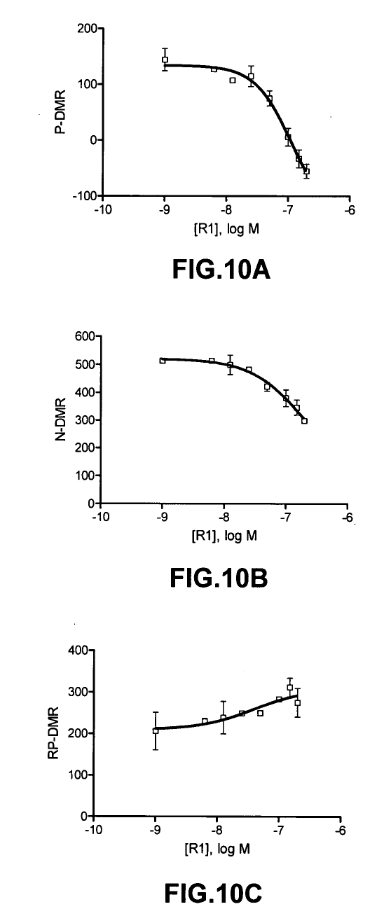

FIGS. 10A to 10C show the amplitudes of dose-dependent real-time kinetic responses of quiescent A431 cells induced by 64 nM of EGF as a function of the concentration of anti-EGFR (R1). The cells were incubated with anti-EGFR (R1) at 37° C. for 24 hours. The data were curve fitted with non-linear regression. FIG. 10A shows the cellular response based on P-DMRs. FIG. 10B shows the cellular responses based on N-DMRs. FIG. 10C shows the cellular responses based on RP-DMRs.

Table 2 compares the impact of the pretreatment of A431 cells with antibody for 2 hrs or 24 hrs on the 64 nM EGF-induced DMR signal. Here % change was calculated based on the difference between the end point (log M=−6.71) and the initial point (log M=−9) of the dose-dependent response curve generated using non-linear regression method. The log M is the logarithm (10) of antibody concentration in molar used in the assay.

TABLE 2
Comparisons of the impact of two different pre-treatment
times of A431 cells with each antibody on the EGF-induced
DMR signal using Epic ® cell-based assays.

| | % change | | | | | |
|---|---|---|---|---|---|---|
| Antibody | 2 hr treatment | | | 24 hr treatment | | |
| clone | P-DMR | N-DMR | RP-DMR | P-DMR | N-DMR | RP-DMR |
| 29.1 | No | No | 33 | −55 | −24 | No effect |
| | effect | effect | | | | |
| 2E9 | ~−100 | −78 | −38 | −78 | 54 | 40 |
| R1 | −69 | No | No effect | ~−100 | −41 | 40 |
| | | effect | | | | |
| 528 | −37 | −46 | −86 | −35 | −58 | −83 |
| C11 | −92 | −32 | No effect | −138 | −29 | 64 |
| 9G6 | −41 | No | No effect | N.D. | N.D. | N.D. |
| | | effect | | | | |

“No effect” was defined as a % change that was below or less than 20% based on the consideration of more prominent bulk index changes at the high end of the concentration of antibody solutions.
The (“−”) sign indicated an inhibitory effect,
the (“+”) sign indicated a stimulating effect,
the (“~”) sign means “about,” and
“N.D.” indicates “not determined”.

In this study, the long term effects of five antibodies (clone 29.1, 2E9, R1, 528, and C11) on A431 cells were examined with 24 hour incubation at 37° C. before the assays. All five antibodies showed inhibitions on the EGFR activation as implicated by decreasing P-DMR response with increasing concentration of each antibody. However, the effects of these antibodies on the EGFR downstream signaling and consequent endocytosis and morphological alteration varied. Some displayed inhibitory effect, while others showed stimulating effect, revealed by positive % change of N-DMRs and RP-DMRs over the range of titration.

In a side-by-side comparison, the assays with a short incubation (2 hr at 28° C.) yielded a different array of results from that of long term incubation. Some of the antibodies showing inhibitions with long term incubation displayed either no effect or the opposite effect, which results suggest the importance of examining a full spectrum of the cellular impacts of antibodies in antibody screening.

The disclosure has been described with reference to various specific embodiments and techniques. However, it should be understood that many variations and modifications are possible while remaining within the spirit and scope of the disclosure.

### REFERENCES

1. Fang Y, et al., “Resonant waveguide grating biosensor for living cell sensing”, Biophys J, 2006; 91, 1925-1940.
2. Fang Y, et al., “Characteristics of dynamic mass redistribution of EGF receptor signaling in living cells measured with label free optical biosensors”, Anal. Chem., 2005; 77: 5720-5725.
3. Fang Y, et al., “Cellular functions of cholesterol probed with optical biosensors”, Biochim Biophys Acta, 2006; 1763, 254-261.
4. Fang, Y., et al., “Non-invasive optical biosensor for assaying endogenous G protein-coupled receptors in adherent cells”, J. Pharmacol. Toxicol. Methods, 55 (2007) 314-220.
5. Fang, Y. “Label-free cell-based assays with optical biosensors in drug discovery”, Assays and Drug Development Technologies, 2006, 4(5), 583-595.
6. U.S. Pat. No. 7,105,347 B2, to Fang, Y., et al., assigned to Corning Inc., entitled “Method and Device for Protein Delivery into Cells.”

What is claimed is:

1. A method for characterizing antibody function in a live-cell, the method comprising:
providing a biosensor having a live-cell immobilized on the biosensor's surface;
contacting the immobilized cell with an antibody against a selected cellular target for a period of time;
contacting the antibody-contacted immobilized cell having the selected cellular target, with a pair of markers, the contacting with the pair of markers being accomplished simultaneously or sequentially;
detecting with the biosensor the effect of the antibody contact on cell-signaling of the cellular target induced by either of the first marker or the second marker; and
comparing the biosensor's signal of the cell-signaling of the cellular target in the presence and absence of the antibody.

2. The method of claim 1 wherein the period of time is selected from the group consisting of from about seconds to about minutes, from about minutes to about hours, from about days to about weeks, and combinations thereof.

3. The method of claim 1 wherein the pair of markers comprises at least one ligand that directly activates the cellular target.

4. The method of claim 1 wherein the pair of markers comprises at least one ligand that indirectly acts on the cellular target by way of activation, transactivation, or both.

5. The method of claim 1 wherein the pair of markers comprises a first marker which directly binds to and activates the cellular target, and a second marker which indirectly transactivates the cellular target through a cellular regulatory or signaling path.

6. The method of claim 1 wherein contacting the immobilized cell with an antibody comprises contacting the cell's surface with the antibody, contacting the cell intracellularly with the antibody, or combinations thereof.

7. The method of claim 1 wherein the cellular target comprises a feature on the cell's surface comprising at least one of a G protein-coupled receptor (GPCR), an ion channel, a receptor tyrosine kinase, an epidermal growth factor receptor (EFGR), a cytokine receptor, an immuno-receptor, an integrin receptor, an ion transporter, or combinations thereof.

8. The method of claim 1 wherein the cellular target comprises an intracellular target comprising at least one of an enzyme, a kinase, a phosphatase, or combinations thereof.

9. The method of claim 1 wherein the cellular target comprises a monomeric receptor, a dimeric receptor, an oligomeric receptor, or combinations thereof.

10. The method of claim 1 wherein the cellular target comprises an homologous receptor complex or an heterologous oligomeric receptor complex.

11. The method of claim 1 wherein the biosensor comprises an impedance sensor, an evanescent wave sensor, or combinations thereof.

12. A method comprising:
providing a biosensor having a live-cell immobilized on the biosensor's surface, the live-cell having at least one cellular target of interest;
incubating the immobilized cell with a protein transfection complex containing an antibody such that the antibody is taken into the cell and thereafter interacts with the cellular target of interest;
stimulating the immobilized cell with a stimulus; and
monitoring the biosensor's signature of the cell's response to the stimulus.

13. The method of claim 12 wherein the protein transfection complex comprises an antibody comprising a liposome or a protein transduction agent.

14. A method for characterizing antibody function against epidermal growth factor receptor (EFGR) cellular target in a live-cell, the method comprising:
providing a biosensor having a live-cell immobilized on the biosensor's surface, the immobilized cell having at least one EFGR target;
contacting the immobilized cell with an antibody against an epidermal growth factor receptor for a period of time;
contacting the antibody-contacted immobilized cell with a marker;
detecting with the biosensor the effect of the antibody contact on the cell-signaling of the EFGR cellular target induced by the marker; and
comparing the biosensor's measure of cell-signaling of the EFGR cellular target in the presence and the absence of the antibody.

15. The method of claim 14 wherein the marker comprises one marker, two markers, or three or more different markers.

16. The method of claim 14 wherein the marker comprises at least one of: an epidermal growth factor (EGF), a methyl-β-cyclodextrin, a G protein-coupled receptor ligand that transactivates epidermal growth factor receptor, or a combination thereof.

17. The method of claim 14 wherein the marker is an EGF.

18. The method of claim 14 wherein the period of time is selected from the group consisting of from about seconds to about minutes, from about minutes to about hours, from about days to about weeks, and combinations thereof.

19. The method of claim 1 wherein the antibody is an auto-antibody.
